(19) United States
(12) Patent Application Publication
(10) Pub. No.: US 2014/0138527 A1
(43) Pub. Date: May 22, 2014

(54) CHARGED PARTICLE BEAM WRITING APPARATUS AND CHARGED PARTICLE BEAM DOSE CHECK METHOD

(71) Applicant: NuFlare Technology, Inc., Yokohama (JP)

(72) Inventors: Yasuo KATO, Kanagawa (JP); Mizuna Suganuma, Kanagawa (JP)

(73) Assignee: NuFlare Technology, Inc., Yokohama (JP)

(21) Appl. No.: 14/079,866

(22) Filed: Nov. 14, 2013

(30) Foreign Application Priority Data
Nov. 21, 2012 (JP) 2012-255312

(51) Int. Cl. H01J 37/302

(52) U.S. Cl. CPC H01J 37/3026
USPC 250/252.1; 250/492.22

(57) ABSTRACT

A charged particle beam writing apparatus according to one aspect of the present invention includes a calculation unit to calculate a dose density that corrects a dimensional variation caused by at least one of a proximity effect, a fogging effect, and a loading effect, and indicates a dose per unit area of a charged particle beam, where the dose density has been modulated based on a dose modulation amount input from outside, a determination unit to determine whether the dose density exceeds an acceptable value, and a writing unit to write a pattern on a target object with the charged particle beam.

### CROSS-REFERENCE TO RELATED APPLICATION

This application is based upon and claims the benefit of priority from the prior Japanese Patent Application No. 2012-255312 filed on Nov. 21, 2012 in Japan, the entire contents of which are incorporated herein by reference.

### BACKGROUND OF THE INVENTION

1. Field of the Invention

The present invention relates to a charged particle beam writing apparatus and a charged particle beam dose check method. More specifically, for example, the present invention relates to a method of checking the dose of a charged particle beam emitted from a writing apparatus.

2. Description of Related Art

The lithography technique that advances miniaturization of semiconductor devices is extremely important as being a unique process whereby patterns are formed in semiconductor manufacturing. In recent years, with high integration of LSI, the line width (critical dimension) required for semiconductor device circuits is decreasing year by year. For forming a desired circuit pattern on such semiconductor devices, a master or “original” pattern (also called a mask or a reticle) of high accuracy is needed. Thus, the electron beam (EB) writing technique, which intrinsically has excellent resolution, is used for producing such a highly precise master pattern.

FIG. 9 is a conceptual diagram explaining operations of a variable shaped electron beam writing or “drawing” apparatus. As shown in the figure, the variable shaped electron beam writing apparatus operates as described below. A first aperture plate 410 has a quadrangular opening 411 for shaping an electron beam 330. A second aperture plate 420 has a variable-shape opening 421 for shaping the electron beam 330 having passed through the opening 411 of the first aperture plate 410 into a desired quadrangular shape. The electron beam 330 emitted from a charged particle source 430 and having passed through the opening 411 is deflected by a deflector to pass through a part of the variable-shape opening 421 of the second aperture plate 420, and thereby to irradiate a target object or “sample” 340 placed on a stage which continuously moves in one predetermined direction (e.g., the x direction) during the writing. In other words, a quadrangular shape that can pass through both the opening 411 and the variable-shape opening 421 is used for pattern writing in a writing region of the target object 340 on the stage continuously moving in the x direction. This method of forming a given shape by letting beams pass through both the opening 411 of the first aperture plate 410 and the variable-shape opening 421 of the second aperture plate 420 is referred to as a variable shaped beam (VSB) method.

In electron beam writing, the problem of dimensional variations caused by a mask process or an unknown mechanism is solved by adjusting the amount of dose of an electron beam. In recent years, at the stage before inputting data into a writing apparatus, the amount of dose modulation for additionally controlling the dose amount is set by a user or a correction tool. However, if there is a deficiency in a value set by the user or a calculation result by the correction tool and the like, when such a value is input into the writing apparatus and used as it is in the writing apparatus, which results in a problem that irradiation is performed with a beam of an unusual amount of dose. This beam irradiation of an unusual amount of dose will cause irregularity of pattern critical dimension (CD). Furthermore, when it is an extremely unusual value, evaporation of the resist and thus contamination of a writing apparatus (or failure of a writing apparatus) by the evaporation may occur. Thus, for example, the dose amount of one-time beam radiation needs to be restricted (refer to, e.g., Japanese Patent Application Laid-open (JP-A) No. 2012-015244). Therefore, a set value of the amount of dose modulation input into the apparatus also needs to be restricted.

On the other hand, in the writing apparatus, correction operation, etc. is performed for a phenomenon, such as the proximity effect, that causes dimensional variations, for example. This makes the dose amount be corrected, and controlled depending upon an operation result in the writing apparatus.

Even if limit is established on a set value of a dose modulation amount which is input from the outside of the writing apparatus, since correction of the dose amount is executed in the writing apparatus, as long as dose modulation is performed in such a state, consequently, there occurs a problem in that a beam of an unusual amount of dose is irradiated in the writing apparatus.

### BRIEF SUMMARY OF THE INVENTION

In accordance with one aspect of the present invention, a charged particle beam writing apparatus includes a calculation unit configured to calculate a dose density that corrects a dimensional variation caused by at least one of a proximity effect, a fogging effect, and a loading effect, and indicates a dose per unit area of a charged particle beam, where the dose density has been modulated based on a dose modulation amount input from outside, a determination unit configured to determine whether the dose density exceeds an acceptable value and a writing unit configured to write a pattern on a target object with the charged particle beam.

In accordance with another aspect of the present invention, a charged particle beam writing apparatus includes a calculation unit configured to calculate a dose of a charged particle beam for correcting a dimensional variation caused by at least one of a proximity effect, a fogging effect, and a loading effect, where the dose has been modulated based on a dose modulation amount input from outside, a determination unit configured to determine whether the dose exceeds an acceptable value, and a writing unit configured to write a pattern on a target object with the charged particle beam.

Moreover, in accordance with another aspect of the present invention, a charged particle beam dose check method includes calculating a dose or a dose density, which indicates a dose per unit area, of a charged particle beam for correcting a dimensional variation caused by at least one of a proximity effect, a fogging effect, and a loading effect, where the dose or the dose density has been modulated based on a dose modulation amount input from outside, and determining, before performing writing processing, whether the dose or the dose density exceeds a corresponding acceptable value, and outputting a result of the determining.

### BRIEF DESCRIPTION OF THE DRAWINGS

FIG. 1 is a schematic diagram showing a structure of a writing apparatus according to the first embodiment;

FIG. 2 shows an example of a figure pattern according to the first embodiment;

FIG. 3 shows an example of dose modulation amount DM data according to the first embodiment;

FIG. 4 is a flowchart showing main steps of a writing method according to the first embodiment;

FIGS. 5A to 5E are conceptual diagrams explaining a flow of generating a dose density map according to the first embodiment;

FIGS. 6A to 6E are conceptual diagrams explaining a flow of generating a dose map according to the first embodiment;

FIG. 7 is a schematic diagram showing the configuration of a writing apparatus according to the second embodiment;

FIG. 8 is a flowchart showing main steps of a writing method according to the second embodiment; and

FIG. 9 is a conceptual diagram explaining operations of a variable shaped electron beam writing apparatus.

### DETAILED DESCRIPTION OF THE INVENTION

In the following embodiments, there will be described a structure in which an electron beam is used as an example of a charged particle beam. The charged particle beam is not limited to the electron beam, and other charged particle beam, such as an ion beam, may also be used. Furthermore, an electron beam writing apparatus of a variable-shaped beam (VSB) type will be described as an example of a charged particle beam apparatus.

Moreover, in the following embodiments, there will be described a dose check method and apparatus by which it is possible to avoid a beam irradiation of an unusual amount of dose caused by a dose modulation amount set outside the apparatus even when dose amount correction is performed in the writing apparatus.

With regard to writing precision, if a dose density per beam irradiation (one writing pass) exceeds a threshold value, the writing precision deteriorates because of the heating effect. Also, if a dose per writing pass exceeds a threshold value, the writing precision deteriorates. Then, in the following embodiments, a maximum dose density and a maximum dose are respectively calculated to be checked by being compared with a respective threshold value before starting writing processing.

### First Embodiment

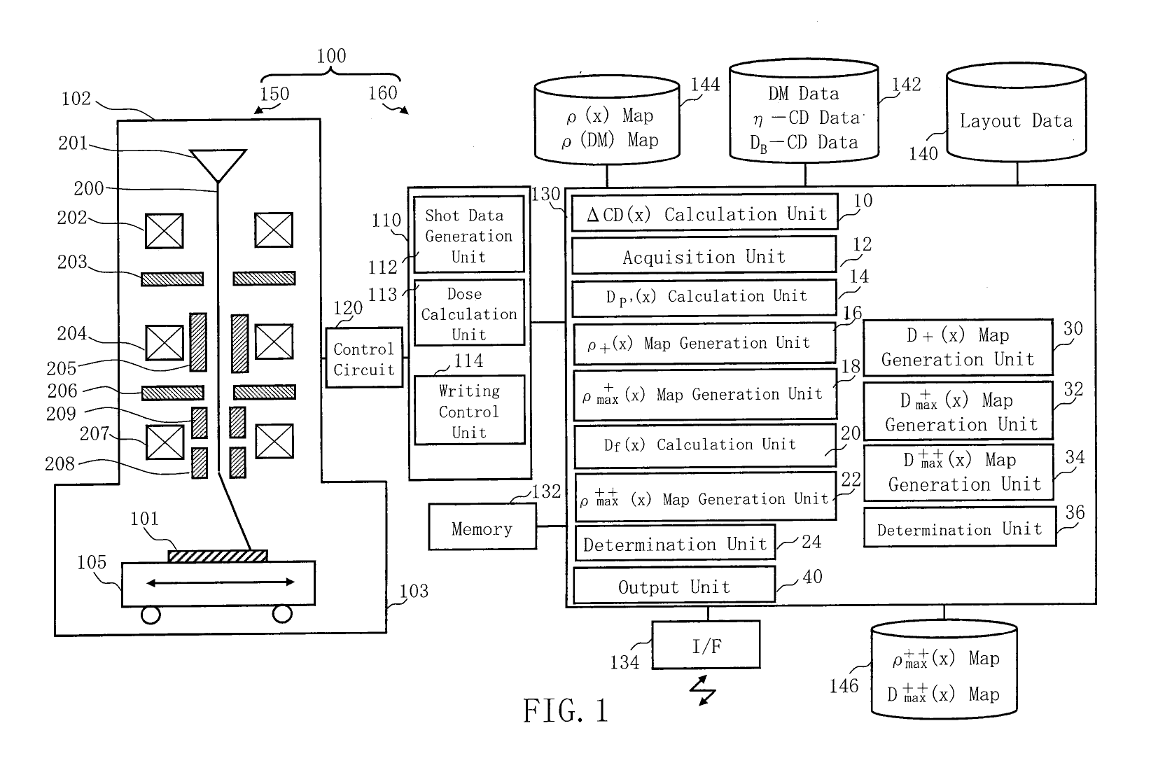

FIG. 1 is a schematic diagram showing a structure of a writing apparatus according to the first embodiment. In FIG. 1, a writing apparatus 100 includes a writing unit 150 and a control unit 160. The writing apparatus 100 is an example of a charged particle beam writing apparatus, and especially, an example of a variable-shaped electron beam writing apparatus. The writing unit 150 includes an electron lens barrel 102 and a writing chamber 103. In the electron lens barrel 102, there are arranged an electron gun assembly 201, an illumination lens 202, a first aperture plate 203, a projection lens 204, a deflector 205, a second aperture plate 206, an objective lens 207, a main deflector 208 and a sub-deflector 209. In the writing chamber 103, there is arranged an XY stage 105. On the XY stage 105, a target object 101, such as a mask, serving as a writing target is placed when writing. The target object 101 is, for example, an exposure mask used when manufacturing semiconductor devices. The target object 101 is, for example, a mask blank on which resist is applied and a pattern has not yet been formed.

The control unit 160 includes a control computer 110, a control circuit 120, a preprocessing computer 130, a memory 132, an external interface (I/F) circuit 134, and storage devices 140, 142, 144, and 146, such as a magnetic disk drive. The control computer 110, the control circuit 120, the preprocessing computer 130, the memory 132, the external interface (I/F) circuit 134, and the storage devices 140, 142, 144, and 146 are mutually connected through a bus (not shown).

In the preprocessing computer 130, there are arranged a dimensional variation amount ΔCD(x) calculation unit 10, an acquisition unit 12, a proximity effect correction dose coefficient Dp′(x) calculation unit 14, a dose density ρ⁺(x) map generation unit 16, a maximum dose density ρ⁺ₘₐₓ(x) map generation unit 18, a fogging effect correction dose coefficient D_{f}(x) calculation unit 20, a maximum dose density ρ⁺⁺ₘₐₓ(x) map generation unit 22, a determination unit 24, a dose D⁺(x) map generation unit 30, a maximum dose D⁺ₘₐₓ(x) map generation unit 32, a maximum dose D⁺⁺ₘₐₓ(x) map generation unit 34, a determination unit 36, and an output unit 40. Each function, such as the dimensional variation amount ΔCD(x) calculation unit 10, the acquisition unit 12, the proximity effect correction dose coefficient Dp′(x) calculation unit 14, the dose density ρ⁺(x) map generation unit 16, the maximum dose density ρ⁺ₘₐₓ(x) map generation unit 18, the fogging effect correction dose coefficient D_{f}(x) calculation unit 20, the maximum dose density ρ⁺⁺ₘₐₓ(x) map generation unit 22, the determination unit 24, the dose D⁺(x) map generation unit 30, the maximum dose D⁺ₘₐₓ(x) map generation unit 32, the maximum dose D⁺⁺ₘₐₓ(x) map generation unit 34, the determination unit 36, and the output unit 40, may be configured by hardware such as an electronic circuit or by software such as a program causing a computer to implement these functions. Alternatively, it may be configured by a combination of hardware and software. Data which is input and output to/from the dimensional variation amount ΔCD(x) calculation unit 10, the acquisition unit 12, the proximity effect correction dose coefficient Dp′(x) calculation unit 14, the dose density ρ⁺(x) map generation unit 16, the maximum dose density ρ⁺ₘₐₓ(x) map generation unit 18, the fogging effect correction dose coefficient D_{f}(x) calculation unit 20, the maximum dose density ρ⁺⁺ₘₐₓ(x) map generation unit 22, the determination unit 24, the dose D⁺(x) map generation unit 30, the maximum dose D⁺ₘₐₓ(x) map generation unit 32, the maximum dose D⁺⁺ₘₐₓ(x) map generation unit 34, the determination unit 36, and the output unit 40 and data being calculated are stored in the memory 132 each time.

In the control computer 110, there are arranged a shot data generation unit 112, a dose calculation unit 113, and a writing control unit 114. Each function, such as the shot data generation unit 112, the dose calculation unit 113, and the writing control unit 114, may be configured by hardware such as an electronic circuit or by software such as a program causing a computer to implement these functions. Alternatively, it may be configured by a combination of hardware and software. Data which is input and output to/from the shot data generation unit 112, the dose calculation unit 113, and the writing control unit 114 and data being calculated are stored in the memory (not shown) each time.

In the storage device 140, layout data (for example, CAD data, etc.) being design data created by the user side is input from the outside to be stored therein. In the storage device 142, dose modulation amount (factor) DM data, correlation data between a proximity effect correction coefficient η and a critical dimension (CD), and correlation data between a base dose D_{B} and a critical dimension (CD) are input from the outside to be stored therein. The dose modulation amount DM is set by the user or a correction tool, etc. at the stage before inputting the data into the writing apparatus 100. It is preferable to define the dose modulation amount DM to be 0% to 200% etc., for example. However, it is not limited thereto. As to the dose modulation factor, it is also preferable to define it to be a value such as 1.0 to 3.0, etc., for example. In the storage device 144, there are stored an area density ρ(x) map and an area density ρ(DM) map in which a dose modulation amount is added. ρ(DM) is defined as a value obtained by multiplying an area density ρ(x) by a dose modulation amount (factor), for example. Here, the position x does not merely indicate the x direction in two dimensions, and it also indicates a vector. The same shall apply hereafter. The area density ρ(x) and the area density ρ(DM) may be calculated in the preprocessing computer 130, or calculated by other computers etc. Alternatively, they may be input from the outside.

FIG. 1 shows a structure necessary for explaining the first embodiment. Other structure elements generally necessary for the writing apparatus 100 may also be included. For example, although a multiple stage deflector namely the two stage deflector of the main deflector 208 and the sub deflector 209 is herein used for position deflection, a single stage deflector or a multiple stage deflector of three or more stages may also be used for position deflection. Moreover, input devices, such as a mouse and a keyboard, and a monitoring device, etc. may also be connected to the writing apparatus 100.

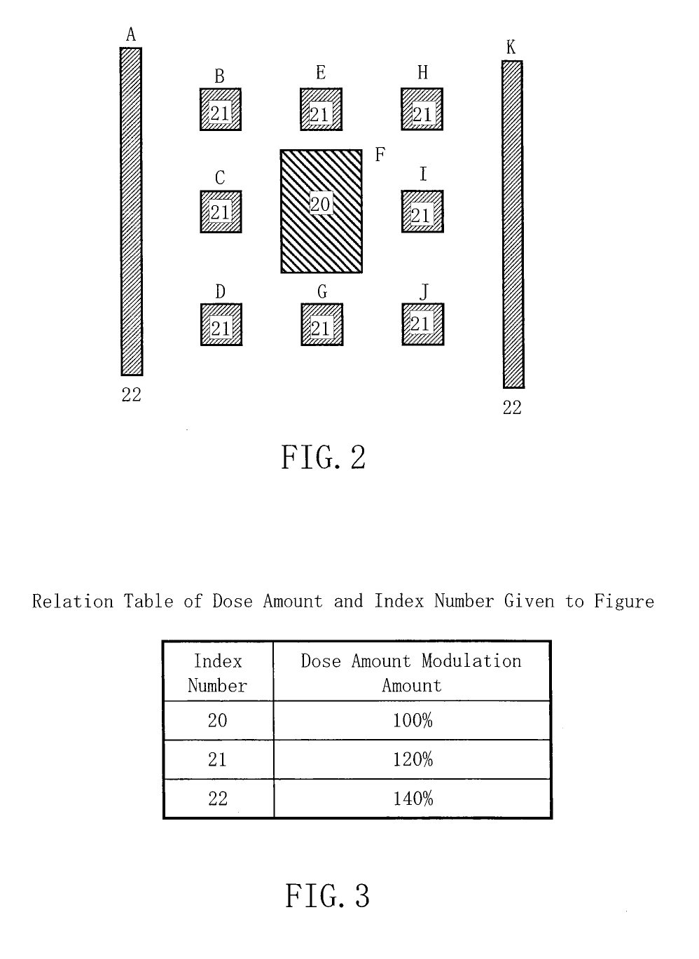

FIG. 2 shows an example of a figure pattern according to the first embodiment. In FIG. 2, for example, a plurality of figure patterns A to K are arranged in the layout data. It may wish to write the figure patterns A and K, the figure patterns B to E and G to J, and the figure pattern F by using different dose amounts. The dose modulation amount DM for the figure patterns A and K, the dose modulation amount DM for figure patterns B to E and G to J, and the dose modulation amount DM for the figure pattern F are set in advance. The dose amount after modulation is calculated as a value obtained by multiplying, for example, a dose D(x) of after calculation of proximity effect correction etc. in the writing apparatus 100 by the dose modulation amount DM.

FIG. 3 shows an example of dose modulation amount DM data according to the first embodiment. As shown in FIG. 2, an index number (identifier) is given to each figure of a plurality of figure patterns in the layout data. As shown in FIG. 3, the dose modulation amount DM data is defined as a dose modulation amount DM for each index number. In FIG. 3, for example, with respect to the figure pattern of the index number 20, the dose modulation amount DM is defined to be 100%. With respect to the figure pattern of the index number 21, the dose modulation amount DM is defined to be 120%. With respect to the figure pattern of the index number 22, the dose modulation amount DM is defined to be 140%. The dose modulation amount DM data is generated by inputting each data of dose modulation amount DM set by the user or the correction tool, etc. and an index number of a figure pattern corresponding to the each data, and making them correspond with each other.

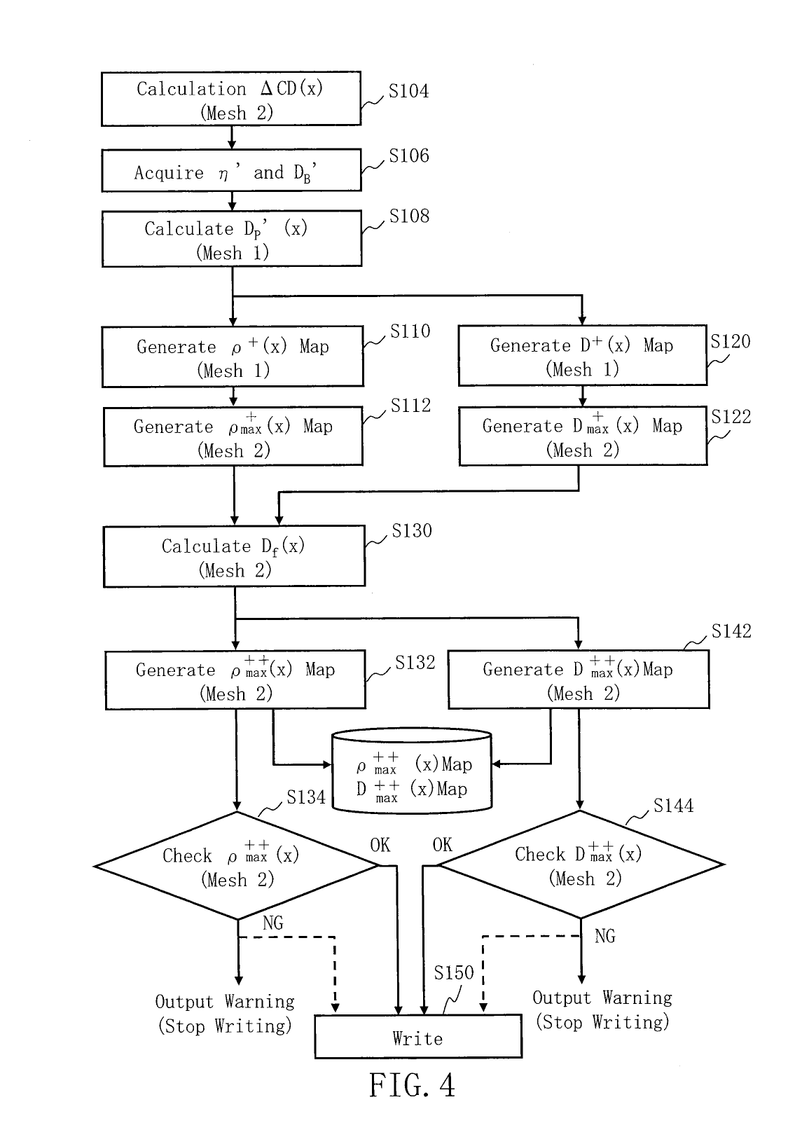

FIG. 4 is a flowchart showing main steps of a writing method according to the first embodiment. FIG. 4 particularly emphasizes on a method of checking a dose of an electron beam. Referring to FIG. 4, the writing method executes a series of steps: a dimensional variation amount ΔCD(x) calculation step (S104), an acquisition step (S106), a proximity effect correction dose coefficient Dp′(x) calculation step (S108), a dose density ρ⁺(x) map generation step (S110), a maximum dose density ρ⁺ₘₐₓ(x) map generation step (S112), a dose D⁺(x) map generation step (S120), a maximum dose D⁺ₘₐₓ(x) map generation step (S122), a fogging effect correction dose coefficient D_{f}(x) calculation step (S130), a maximum dose density ρ⁺⁺ₘₐₓ(x) map generation step (S132), a determination step (S134), a maximum dose D⁺⁺ₘₐₓ(x) map generation step (S142), a determination step (S144), and a writing step (S150).

In the ΔCD(x) calculation step (S104), the ΔCD(x) calculation unit 10 reads an area density ρ(x) from the storage device 144, and calculates a dimensional variation amount ΔCD(x) resulting from the loading effect. The dimensional variation amount ΔCD(x) is defined by the following equation (1).

ΔCD=γ∫ρ(x′)g_{L}(x−x′)dx′+P(x) (1)

Here, the loading effect correction coefficient γ is defined by the dimensional variation amount at the area density of 100%. g_{L}(x) indicates a distribution function in the loading effect. P(x) indicates a position dependent dimensional variation amount. The data stored in the storage device, etc. (not shown) may be used as the position dependent dimensional variation amount P(x). The chip region of a chip used as a writing target is virtually divided into a plurality of mesh regions (mesh 2: second mesh region) and calculation is performed for each mesh region (mesh 2). It is preferable for the size (the second size) of the mesh region (mesh 2) to be, for example, about 1/10 of the influence radius of the loading effect. For example, it is preferable to be about 100 to 500 μm.

In the acquisition step (S106), the acquisition unit 12 reads correlation data (η-CD) between n and CD and correlation data (D_{B}-CD) between D_{B} and CD from the storage device 142, and acquires a group of a proximity effect correction coefficient (back scattering coefficient) η′ and a base dose D_{B}′, wherein the proximity effect correction coefficient η′ is suitable for correcting even a dimensional variation amount ΔCD(x) resulting from the loading effect while maintaining proximity effect correction. It is preferable to acquire a group of η′ and D_{B} suitable for a CD obtained by adding (or subtracting) a dimensional variation amount ΔCD(x) to a desired CD based on the correlation data between η and CD and the correlation data between D_{B} and CD. In the case where the proximity effect correction coefficient η and the base dose D_{B} which do not take the loading effect into account are set in advance, the group of η′ and D_{B}′ is acquired instead of these η and D_{B}.

In the Dp′(x) calculation step (S108), the Dp′(x) calculation unit 14 reads an area density ρ (DM: x) from the storage device 144, and calculates a proximity effect correction dose coefficient Dp′(x) for correcting the proximity effect further by using the obtained η′. The proximity effect correction dose coefficient Dp′(x) can be obtained by solving the following equation (2).

$$\frac{{D}_{p}^{′} ( x )}{2} + {η}^{′} \int {D}_{p}^{′} ( {x}^{′} ) {g}_{p} ( x - {x}^{′} ) ρ ( DM \text{:} {x}^{′} ) d {x}^{′} = \frac{1}{2} + {η}^{′} \qquad ( 2 )$$

Here, gₚ(x) indicates a distribution function (back scattering influence function) in the proximity effect. Calculation is performed for each mesh region (mesh 1) which is obtained by virtually dividing the chip region of a chip used as a writing target into a plurality of mesh regions (mesh 1: the first mesh region). It is preferable for the size (the first size) of the mesh region (mesh 1) to be, for example, about several times of 1/10 of the influence radius of the proximity effect. For example, it is preferable to be about 5 to 10 μm. Thereby, the number of times of calculation can be reduced compared with a particular calculation of proximity effect correction performed for each mesh region of the size of about 1/10 of the influence radius of the proximity effect. As a result, it is possible to perform calculation at high speed.

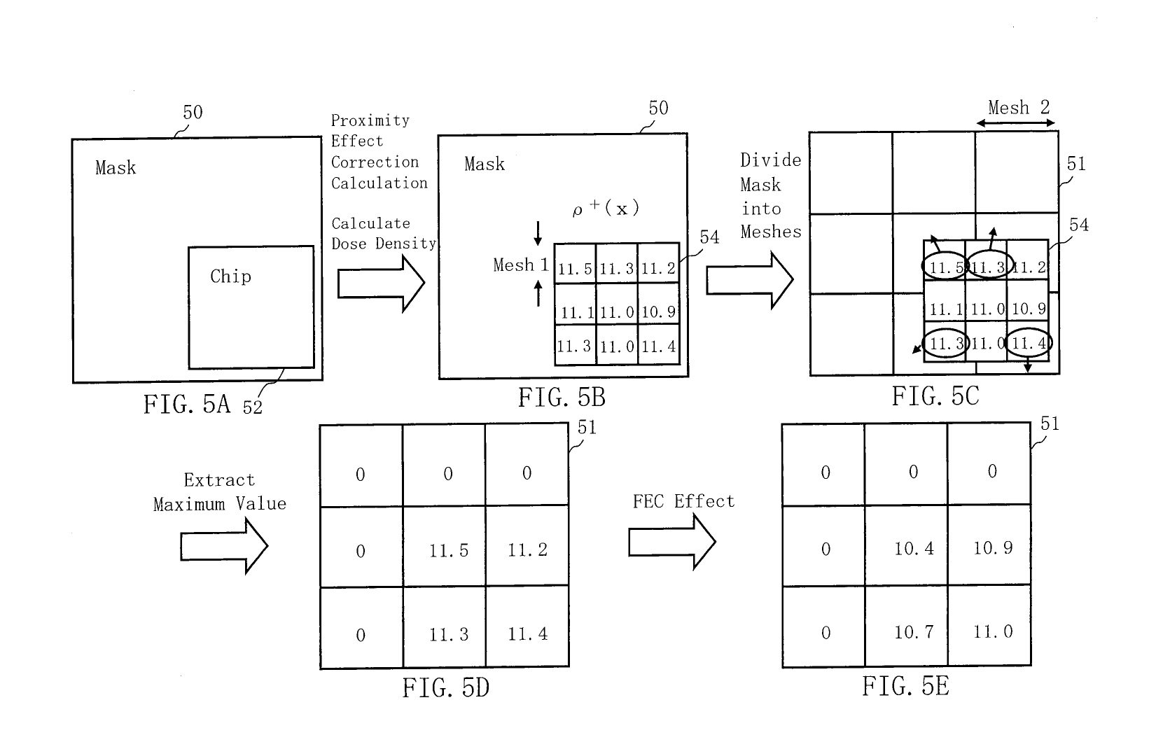

FIGS. 5A to 5E are conceptual diagrams explaining a flow of generating a dose density map according to the first embodiment. As shown in FIG. 5A, a chip 52 is to be written on a target object 50. First, as shown in FIG. 5B, a ρ⁺(x) map in which a dose density ρ⁺(x) indicating a dose per unit area is defined for each mesh region (mesh 1) 54.

In the ρ⁺(x) map generation step (S110), the ρ⁺(x) map generation unit 16 calculates a dose density ρ⁺(x) for each mesh region (mesh 1), and generates a ρ⁺(x) map in which a dose density ρ⁺(x) is defined for each mesh region (mesh 1). The dose density ρ⁺(x) is obtained by solving the following equation (3). In the ρ⁺(x) map, a dose density ρ⁺(x) in which the proximity effect and the loading effect have been corrected is defined.

ρ⁺(x)=D_{B}′(x)Dₚ′(x)ρ(DM:x) (3)

Here, D_{B}′ in which the loading effect correction is also considered is used as the base dose D_{B}′. The area density ρ(DM: x) is to be read from the storage device 144. The dose density ρ⁺(x) is a dose density to correct for dimensional variations caused by the proximity effect and the loading effect. As shown in the equation (3), the dose density ρ⁺(x) is defined using the base dose D_{B}′, the proximity effect correction dose coefficient Dp′(x) (an example of the dose coefficient) for correcting dimensional variations caused by the proximity effect and the loading effect, and the pattern area density ρ (DM: x) which is weighted by the amount of dose modulation described above.

In the maximum dose density ρ⁺ₘₐₓ(x) map generation step (S112), the ρ⁺ₘₐₓ(x) map generation unit 18 extracts a maximum dose density ρ⁺ₘₐₓ(x) for each mesh region (mesh 2) by using the ρ⁺(x) map, and generates a ρ⁺ₘₐₓ(x) map in which a maximum dose density ρ⁺ₘₐₓ(x) is defined for each mesh region (mesh 2). As shown in FIG. 5C, if there are a plurality of smaller mesh regions (mesh 1) which overlap with at least a part of larger mesh regions (mesh 2), a maximum dose density ρ⁺ₘₐₓ(x) can be obtained as the maximum value extracted from ρ⁺ₘₐₓ(x) defined in a plurality of mesh regions (mesh 1). Then, as shown in FIG. 5D, a ρ⁺ₘₐₓ(x) map in which the maximum dose density ρ⁺ₘₐₓ(x) is defined for each mesh region (mesh 2) 51 is generated. In the ρ⁺ₘₐₓ(x) map, ρ⁺ₘₐₓ(x) in which the proximity effect and the loading effect have been corrected is defined.

In the fogging effect correction dose coefficient D_{f}(x) calculation step (S130), the fogging effect correction dose coefficient D_{f}(x) calculation unit 20 reads an area density ρ (DM: x) from the storage device 144, and calculates a fogging effect correction dose coefficient D_{f}(x) for correcting the fogging effect by using the obtained Dp′(x). The fogging effect correction dose coefficient D_{f}′(x) can be obtained by solving the following equation (4).

$$\frac{{D}_{p}^{′} ( x ) {D}_{f} ( x )}{2} + {η}^{′} \int {D}_{p}^{′} ( {x}^{′} ) {D}_{f} ( {x}^{′} ) {g}_{p} ( x - {x}^{′} ) ρ ( DM \text{:} {x}^{′} ) d {x}^{′} + θ \int {D}_{p}^{′} ( {x}^{′} ) {g}_{f} ( x - {x}^{′} ) ρ ( DM \text{:} {x}^{′} ) d {x}^{′} = \frac{1}{2} + {η}^{′} \qquad ( 4 )$$

Here, g_{f}(x) indicates a distribution function (fogging effect influence function) in the fogging effect, and is calculated for each mesh region (mesh 2). θ indicates a fogging effect correction coefficient.

In the ρ⁺⁺ₘₐₓ(x) map generation step (S132), the ρ⁺⁺ₘₐₓ(x) map generation unit 22 calculates a maximum dose density ρ⁺⁺ₘₐₓ(x) for each mesh region (mesh 2) by using the obtained fogging effect correction dose coefficient D_{f}(x), and, as shown in FIG. 5E, generates a ρ⁺⁺ₘₐₓ(x) map in which the maximum dose density ρ⁺⁺ₘₐₓ(x) is defined for each mesh region (mesh 2) 51. The maximum dose density ρ⁺⁺ₘₐₓ(x) can be obtained by solving the following equation (5).

ρ⁺⁺ₘₐₓ(x)=D_{f}(x)ρ⁺ₘₐₓ(x) (5)

ρ⁺⁺ₘₐₓ(x) in which the proximity effect, the loading effect, and the fogging effect have been corrected is defined in the ρ⁺⁺ₘₐₓ(x) map. The generated ρ⁺⁺ₘₐₓ(x) map is stored as a log in the storage device 146 by the output unit 40. Thereby, a rough maximum dose density can be checked before and after writing.

As described above, by using each above-described calculation unit, a dose density is calculated which corrects for dimensional variations caused by the proximity effect, the fogging effect, and the loading effect, and which indicates a dose per unit area of an electron beam where dose modulation has been performed based on a dose modulation amount input from the outside. Here, although a maximum dose density which corrects for dimensional variations resulting from the proximity effect, the fogging effect, and the loading effect is calculated as an example, it is not limited thereto. It is also preferable to calculate a dose density which corrects for dimensional variations caused by at least one of the proximity effect, the fogging effect, and the loading effect, and which indicates a dose per unit area of an electron beam where dose modulation has been performed based on a dose modulation amount input from the outside.

In the determination step (S134), the determination unit 24 determines whether the dose density exceeds an acceptable value. Specifically, it is determined based on whether the following equation (6) is satisfied or not.

$$\frac{{ρ}_{max}^{++} ( x )}{pass} = \frac{{[ {D}_{B}^{′} ( x ) ρ ( DM \text{:} x ) {D}_{p}^{′} ( x ) ]}_{max} {D}_{f} ( x )}{pass} > {D}_{th}^{( 1 )} \qquad ( 6 )$$

Here, it is determined whether the maximum dose density ρ⁺⁺ₘₐₓ(x) per writing pass exceeds a threshold value Dₜₕ⁽¹⁾. The determination unit 24 determines whether a dose density exceeds the threshold value Dₜₕ⁽¹⁾ for each mesh region (mesh 2). If there is a mesh region (mesh 2) in which the dose density exceeds the threshold value, it is regarded as a no-good status and the output unit 40 outputs a warning. The warning may be displayed on the monitor, etc. (not shown) or may be output to the outside through the external I/F circuit 134. Thereby, the user can be given an index to determine to write or not to write. It is preferable that the warning specifies the mesh region (mesh 2). This makes it possible to alter the amount of dose modulation of that area. Alternatively, writing may be stopped based on the warning.

As described above, with respect to the dose density, even when dose amount correction is performed in the writing apparatus, it is possible to avoid beam irradiation of an unusual dose density caused by a dose modulation amount set outside the apparatus. Consequently, irregularity of the pattern critical dimension (CD), evaporation of the resist, and contamination of the writing apparatus (or failure of the writing apparatus) which are resulting from beam irradiation of an unusual dose density can be avoided. Next, the dose will be checked.

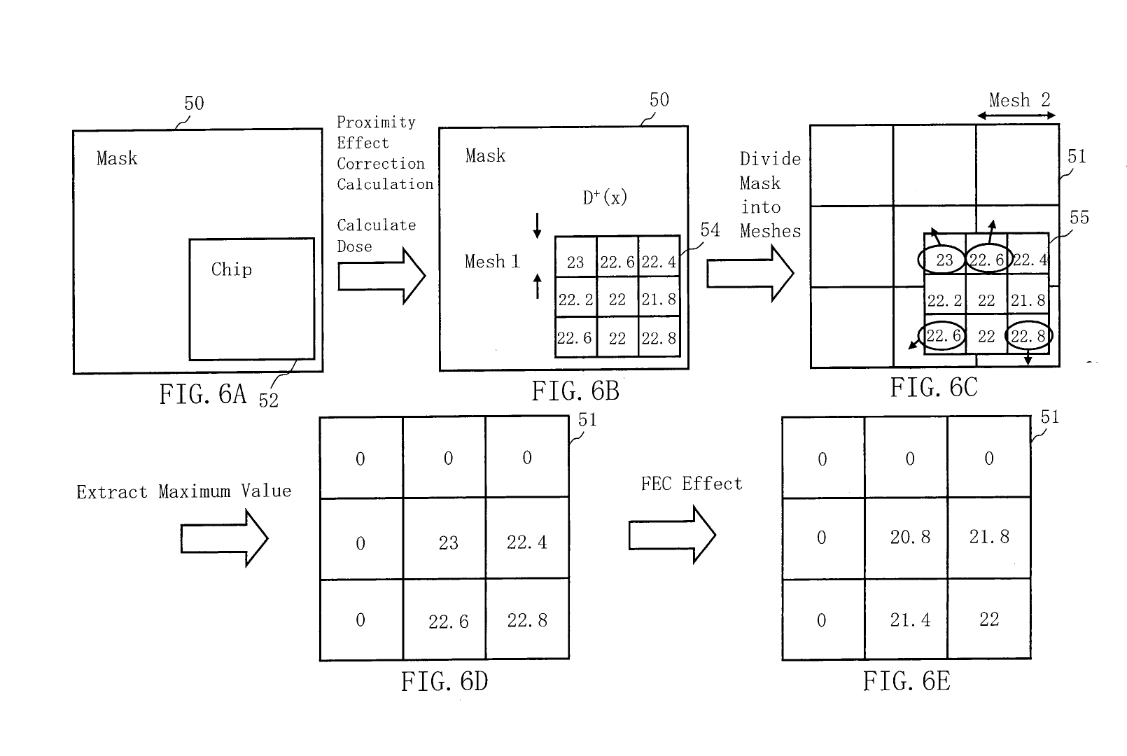

FIGS. 6A to 6E are conceptual diagrams explaining a flow of generating a dose map according to the first embodiment. As shown in FIG. 6A, the chip 52 is to be written on the target object 50. First, as shown in FIG. 6B, a D⁺(x) map in which a dose D⁺(x) is defined for each mesh region (mesh 1) 55 is generated.

In the D⁺(x) map generation step (S120), the D⁺(x) map generation unit 30 calculates a dose D⁺(x) for each mesh region (mesh 1), and generates a D⁺(x) map in which a dose D⁺(x) is defined for each mesh region (mesh 1). The dose D⁺(x) can be obtained by solving the following equation (7). In the Dose D⁺(x) map, the dose D⁺(x) in which the proximity effect and the loading effect have been corrected is defined.

D⁺(x)=D_{B}′(x)Dₚ′(x)DM(x) (7)

Here, as described above, D_{B}′ in which the loading effect correction is also considered is used as the base dose D_{B}′. With regard to the proximity effect correction dose coefficient Dp′(x) a value having already been calculated may be used. The dose modulation amount DM(x) may be read from the storage device 142, or a value having already been read out may be diverted. The dose modulation amount DM(x) may be defined by a value depending upon the position x, or defined for each figure pattern as explained in FIG. 2, etc. When the dose modulation amount DM(x) is defined for each figure pattern, the same value may be used at positions x in each figure pattern.

In the maximum dose D⁺ₘₐₓ(x) map generation step (S122) the D⁺ₘₐₓ(x) map generation unit 32 extracts a maximum dose D⁺ₘₐₓ(x) for each mesh region (mesh 2) by using the D⁺(x) map, and generates a D⁺ₘₐₓ(x) map in which a maximum dose D⁺ₘₐₓ(x) is defined for each mesh region (mesh 2). With regard to a maximum dose D⁺ₘₐₓ(x), as shown in FIG. 6C, if there are a plurality of smaller mesh regions (mesh 1) 55 which overlap with at least a part of larger mesh regions (mesh 2) 51, a maximum value may be extracted from D⁺ₘₐₓ(x) defined in a plurality of mesh regions (mesh 1). As shown in FIG. 6D, a D⁺ₘₐₓ(x) map in which a maximum dose D⁺ₘₐₓ(x) is defined for each mesh region (mesh 2) 51 is generated. D⁺ₘₐₓ(x) in which the proximity effect and the loading effect have been corrected is defined in the D⁺ₘₐₓ(x) map.

In the D⁺⁺ₘₐₓ(x) map generation step (S142), the D⁺⁺ₘₐₓ(x) map generation unit 34 calculates a maximum dose D⁺⁺ₘₐₓ(x) for each mesh region (mesh 2) by using the obtained fogging effect correction dose coefficient D_{f}(x), and, as shown in FIG. 6E, generates a D⁺⁺ₘₐₓ (x) map in which a maximum dose D⁺⁺ₘₐₓ(x) is defined for each mesh region (mesh 2) 51. The maximum dose D⁺⁺ₘₐₓ(x) can be obtained by solving the following equation (8).

D⁺⁺ₘₐₓ(x)=D_{f}(x)D⁺ₘₐₓ(x) (8)

D⁺⁺ₘₐₓ(x) in which the proximity effect, the loading effect, and the fogging effect have been corrected is defined in the D⁺⁺ₘₐₓ(x) map. The generated D⁺⁺ₘₐₓ(x) map is stored as a log in the storage device 146 by the output unit 40. Thereby, a rough maximum dose can be checked before and after writing.

As described above, by using each above-described calculation unit, the dimensional variation caused by the proximity effect, the fogging effect, and the loading effect is corrected, and a dose of an electron beam for correcting the dimensional variation caused by the proximity effect, the fogging effect, and the loading effect, where the dose has been modulated based on a dose modulation amount input from the outside, is calculated. Although, here, a maximum dose which corrects for dimensional variations resulting from the proximity effect, the fogging effect, and the loading effect is calculated as an example, it is not limited thereto. It is also preferable that a dimensional variation caused by at least one of the proximity effect, the fogging effect, and the loading effect is corrected, and, a dose of an electron beam where dose modulation has been performed based on a dose modulation amount input from the outside is calculated.

In the determination step (S144), the determination unit 36 determines whether the dose exceeds an acceptable value or not. Specifically, it is determined based on whether the following equation (9) is satisfied or not.

$$\frac{{D}_{max}^{++} ( x )}{pass} = \frac{{[ {D}_{B}^{′} ( x ) DM ( x ) {D}_{p}^{′} ( x ) ]}_{max} {D}_{f} ( x )}{pass} > {D}_{th}^{( 2 )} \qquad ( 9 )$$

Here, it is determined whether a maximum dose D⁺⁺ₘₐₓ(x) per writing pass exceeds the threshold value Dₜₕ⁽²⁾. The determination unit 36 determines whether a dose exceeds the threshold value Dₜₕ⁽²⁾ or not for each mesh region (mesh 2). If there is a mesh region (mesh 2) in which the dose exceeds the threshold value, it is regarded as a no-good status and the output unit 40 outputs a warning. The warning may be displayed on the monitor, etc. (not shown) or may be output to the outside through the external I/F circuit 134. Thereby, the user can be given an index to determine to write or not to write. It is preferable that the warning specifies the mesh region (mesh 2). This makes it possible to alter the amount of dose modulation of that area. Alternatively, writing may be stopped by the warning.

As described above, with respect to the dose, even when dose amount correction is performed in the writing apparatus, it is possible to avoid beam irradiation of an unusual dose caused by a dose modulation amount set outside the apparatus. Consequently, irregularity of the pattern critical dimension (CD), evaporation of the resist, and contamination of the writing apparatus (or failure of the writing apparatus) which are resulting from beam irradiation of an unusual dose can be avoided.

Although the maximum dose density and the maximum dose are calculated and checked respectively in the above explanation, it is not limited thereto. Even if checking is performed for only one of them, there is an effect of avoiding beam irradiation of an unusual amount of dose.

In the writing step (S150), the writing unit 150 writes a pattern on the target object 101 with the electron beam 200. Depending upon a result of checking the maximum dose density and the maximum dose, when proceeding writing processing, it operates as follows: The shot data generation unit 112 reads writing data from the storage device 140, and performs data conversion processing of a plurality of steps so as to generate apparatus-specific shot data. In order to write a figure pattern by the writing apparatus 100, it needs to divide each figure pattern defined in the writing data to be the size that can be irradiated by one beam shot. Then, in order to actually perform writing, the shot data generation unit 112 divides each figure pattern into the size that can be irradiated by one beam shot so as to generate a shot figure. Shot data is generated for each shot figure. In the shot data, there is defined figure data, such as a figure kind, a figure size, and an irradiation position, for example.

The dose calculation unit 113 calculates a dose D(x) for each mesh region of a predetermined size. The dose D(x) can be obtained by the following equation (10).

D(x)=D_{B}′(x)Dₚ′(x)DM(x)D_{f}(x) (10)

By the equation (10), the dose of an electron beam for correcting dimensional variations caused by the proximity effect, the fogging effect, and the loading effect, where the dose of an electron beam has been modulated based on a dose modulation amount input from the outside, can be calculated. When calculating a proximity effect correction dose coefficient Dp′(x), it is preferable to perform calculation in a mesh region (mesh 3) smaller than the mesh region (mesh 1) described above. For example, about 1/10 of the influence radius of the proximity effect is suitable as the size of the mesh region (mesh 3). For example, it is preferable to be about 0.5 to 1 μm. Moreover, when performing a multi-pass writing, the dose per writing pass can be obtained by being divided by multiplicity, for example.

The writing control unit 114 outputs a control signal to the control circuit 120 in order to perform writing processing. The control circuit 120 inputs shot data and data of each correction dose, and controls the writing unit 150 based on the control signal from the writing control unit 114. The writing unit 150 writes a figure pattern concerned on the target object 100 with the electron beam 200. Specifically, it operates as follows:

The electron beam 200 emitted from the electron gun 201 (emission unit) irradiates the entire first aperture plate 203 having a quadrangular opening by the illumination lens 202. At this point, the electron beam 200 is shaped to be a quadrangle. Then, after having passed through the first aperture plate 203, the electron beam 200 of a first aperture image is projected onto the second aperture plate 206 by the projection lens 204. The first aperture image on the second aperture plate 206 is deflection-controlled by the deflector 205 so as to change the shape and size of the beam to be variably shaped. After having passed through the second aperture plate 206, the electron beam 200 of a second aperture image is focused by the objective lens 207 and deflected by the main deflector 208 and the sub deflector 209, and reaches a desired position on the target object 101 on the XY stage 105 which moves continuously. FIG. 1 shows the case of using a multiple stage deflection, namely the two stage deflector of the main and sub deflectors, for position deflection. In such a case, what is needed is to deflect the electron beam 200 of a shot concerned to the reference position of a subfield (SF), which is obtained by further dividing the stripe region virtually, by the main deflector 208 while following the stage movement, and to deflect the beam of the shot concerned to each irradiation position in the SF by the sub deflector 209.

As described above, according to the first embodiment, resist scattering can be prevented. Furthermore, writing precision degradation caused by heating can be detected before writing. Moreover, a dose (density) map can be used as input data for (automatic) write pass dividing in the apparatus.

### Second Embodiment

In the first embodiment, when acquiring a proximity effect correction coefficient η and a base dose D_{B}, a value in which loading effect correction is considered is acquired, but it is not limited thereto. In the second embodiment, loading effect correction is performed by another method.

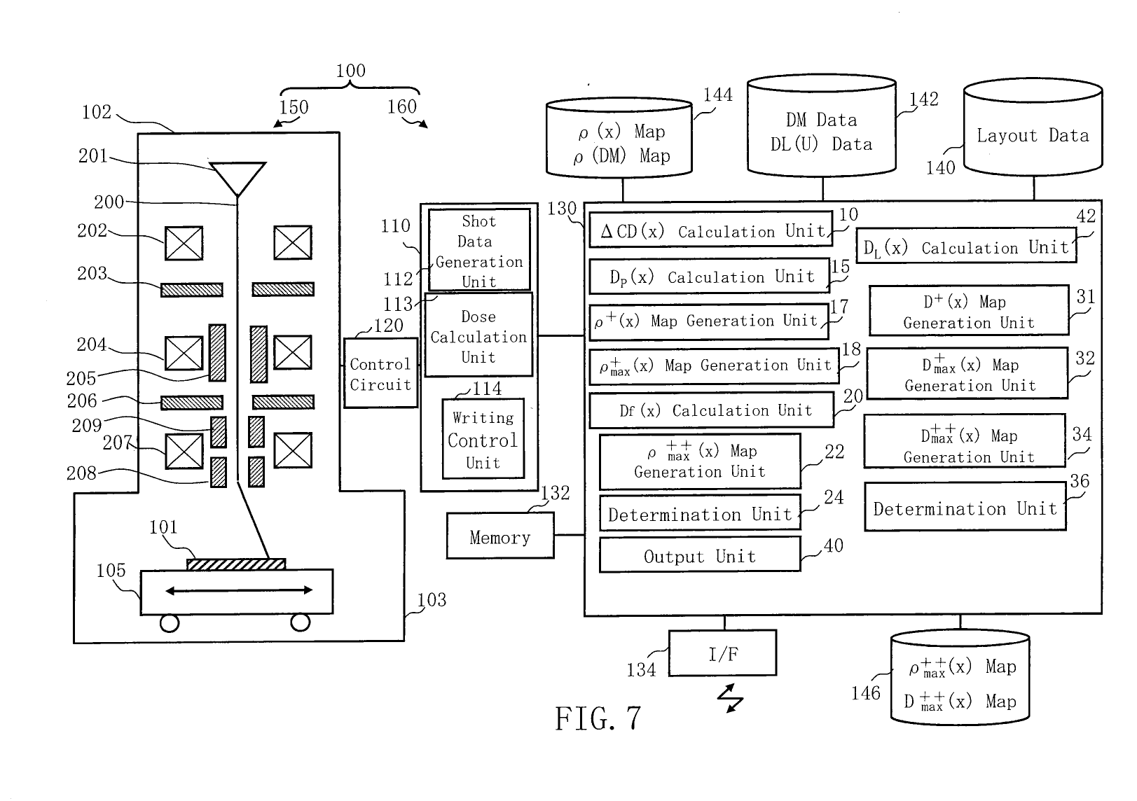

FIG. 7 is a schematic diagram showing the configuration of a writing apparatus according to the second embodiment. FIG. 7 is the same as FIG. 1 except that a loading effect correction dose coefficient D_{L}(x) calculation unit 42, a proximity effect correction dose coefficient Dp(x) calculation unit 15, a dose density ρ⁺(x) map generation unit 17, and a dose D⁺(x) map generation unit 31 are arranged in the preprocessing computer 130, instead of the acquisition unit 12, the proximity effect correction dose coefficient Dp′(x) calculation unit 14, the dose density ρ⁺(x) map generation unit 16, and the dose D⁺(x) map generation unit 30, and that dose modulation amount (factor) DM data and dose latitude DL (U) data are input from the outside to be stored in the storage device 142.

Each function, such as the dimensional variation amount ΔCD(x) calculation unit 10, the loading effect correction dose coefficient D_{L}(x) calculation unit 42, the proximity effect correction dose coefficient Dp(x) calculation unit 15, the dose density ρ⁺(x) map generation unit 17, the maximum dose density ρ⁺ₘₐₓ(x) map generation unit 18, the fogging effect correction dose coefficient D_{f}(x) calculation unit 20, the maximum dose density ρ⁺⁺ₘₐₓ(x) map generation unit 22, the determination unit 24, the dose D⁺(x) map generation unit 31, the maximum dose D⁺ₘₐₓ(x) map generation unit 32, the maximum dose D⁺⁺ₘₐₓ(x) map generation unit 34, the determination unit 36, and the output unit 40, which are all arranged in the preprocessing computer 130, may be configured by hardware such as an electronic circuit or by software such as a program causing a computer to implement these functions. Alternatively, it may be configured by a combination of hardware and software. Data which is input and output to/from the dimensional variation amount ΔCD(x) calculation unit 10, the loading effect correction dose coefficient D_{L}(x) calculation unit 42, the proximity effect correction dose coefficient Dp(x) calculation unit 15, the dose density ρ⁺(x) map generation unit 17, the maximum dose density ρ⁺ₘₐₓ(x) map generation unit 18, the fogging effect correction dose coefficient D_{f}(x) calculation unit 20, the maximum dose density ρ⁺⁺ₘₐₓ(x) map generation unit 22, the determination unit 24, the dose D⁺(x) map generation unit 31, the maximum dose D⁺ₘₐₓ(x) map generation unit 32, the maximum dose D⁺⁺ₘₐₓ(x) map generation unit 34, the determination unit 36, and the output unit 40 and data being calculated are stored in the memory 132 each time.

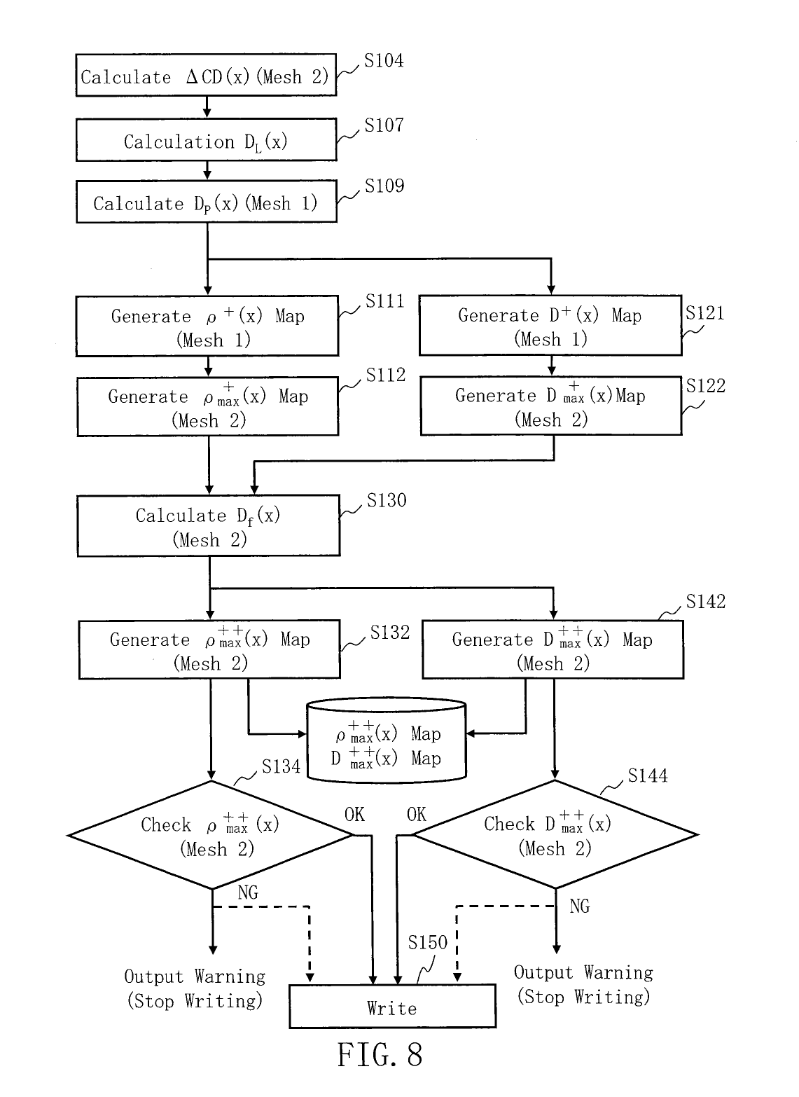

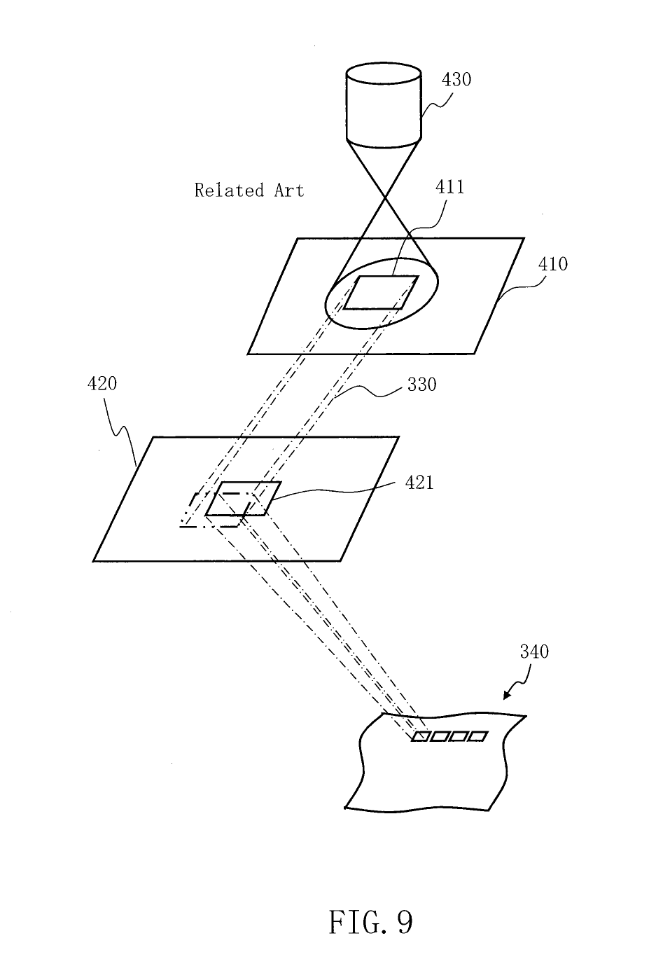

FIG. 8 is a flowchart showing main steps of a writing method according to the second embodiment. FIG. 8 is the same as FIG. 4 except that a loading effect correction dose coefficient D_{L}(x) calculation step (S107), a proximity effect correction dose coefficient Dp(x) calculation step (S109), a dose density ρ⁺(x) map generation step (S111), and a dose D⁺(x) map generation step (S121) are performed instead of the acquisition step (S106), the proximity effect correction dose coefficient Dp′(x) calculation step (S108), the dose density ρ⁺(x) map generation step (S110) and the dose D⁺(x) map generation step (S120). The content of the second embodiment is the same as that of the first embodiment except what is particularly described below.

In the D_{L}(x) calculation step (S107), the D_{L}(x) calculation unit 42 reads dose latitude DL(U) data from the storage device 142, and calculates a loading effect correction dose coefficient D_{L}(x) by using the dimensional variation amount ΔCD(x).

With respect to the dose latitude DL(U) data, a plurality of dose latitudes DL(U) are used as parameters, for example. First, correlation data between a pattern critical dimension (CD) and a dose D is acquired by experiment for each proximity effect density U. A proximity effect density U(x) is defined by a value obtained by convolving a pattern area density ρ(x) in the mesh region (mesh 1) for the proximity effect with a distribution function g(x), in the range greater than or equal to the proximity effect range. It is preferable to use, for example, a Gaussian function as the distribution function g(x). For example, with regard to each of the cases of the proximity effect density U(x)=0 (0%), 0.5 (50%), and 1 (100%), a critical dimension (CD) of a pattern to be written with an electron beam and a dose D(U) of the electron beam are obtained in advance by experiment. The dose latitude DL(U) represents the relation between the pattern critical dimension (CD) and the dose D(U). The dose latitude DL(U) is dependent upon a proximity effect density U(x, y), and, for example, defined by a gradient (proportionality coefficient) of a graph of CD and D(U) of each proximity effect density U(x, y).

A plurality of dose latitudes DL(U) are input into the storage device 142 from the user side (the outside of the apparatus) and stored therein. In this case, the dose latitude DL(Ui) of each of the cases of the proximity effect density U(x, y)=0 (0%), 0.5 (50%), and 1 (100%) is input. Although the dose latitudes DL(Ui) of proximity effect densities U(x) of three points are input in this case, three or more (at least three) points are acceptable. The dose latitude DL(U) can be obtained by fitting a plurality of dose latitudes DL(Ui) by using a polynomial. It is also preferable to store a dose latitude DL(U) for which fitting has been performed in advance by using a polynomial, in the storage device 142.

Next, the loading effect correction dose coefficient D_{L}(x) is defined by the following equation (11) using the dose latitude DL(U) and the dimensional variation amount ΔCD(x).

$${D}_{L} ( x ) = exp ( \frac{- Δ CD}{DL ( U )} ) \qquad ( 11 )$$

In the Dp(x) calculation step (S109), the Dp(x) calculation unit 15 calculates a proximity effect correction dose coefficient Dp(x) for correcting the proximity effect by using a proximity effect correction coefficient (back scattering coefficient) η suitable for correcting a dimensional variation amount ΔCD(x) caused by the proximity effect. η is a coefficient in which loading effect correction is not considered. The proximity effect correction dose coefficient Dp(x) can be obtained by solving the following equation (12).

$$\frac{{D}_{p}}{2} + η \int {D}_{p} ( {x}^{′} ) {g}_{p} ( x - {x}^{′} ) ρ ( DM \text{:} {x}^{′} ) d {x}^{′} = \frac{1}{2} + η \qquad ( 12 )$$

Therefore, the obtained proximity effect correction dose coefficient Dp(x) is a coefficient in which loading effect correction is not taken into consideration. Calculation is performed for each mesh region (mesh 1) which is obtained by virtually dividing the chip region of a chip used as a writing target into a plurality of mesh regions (mesh 1: the first mesh region). It is preferable for the size (the first size) of the mesh region (mesh 1) to be, for example, about several times of 1/10 of the influence radius of the proximity effect. For example, it is preferable to be about 5 to 10 μm. Thereby, the number of times of calculation can be reduced compared with a particular calculation of proximity effect correction performed for each mesh region of the size of about 1/10 of the influence radius of the proximity effect. As a result, it is possible to perform calculation at high speed.

In the ρ⁺(x) map generation step (S111), the ρ⁺(x) map generation unit 17 calculates a dose density ρ⁺(x) for each mesh region (mesh 1), and generates a ρ⁺(x) map in which a dose density ρ⁺(x) is defined for each mesh region (mesh 1). The dose density ρ⁺(x) is obtained by solving the following equation (13). In the ρ⁺(x) map, a dose density ρ⁺(x) in which the proximity effect and the loading effect have been corrected is defined.

ρ⁺(x)=D_{L}(x)D_{B}(x)Dₚ(x)ρ(DM:x) (13)

Here, D_{B} grouped with the proximity effect correction coefficient (back scattering coefficient) η which is suitable for correcting a dimensional variation amount ΔCD(x) resulting from the proximity effect is used as the base dose D_{B}. Loading effect correction is not considered in the base dose D_{B}.

The method of checking a dose density is the same as that of the first embodiment. As described above, loading effect correction may be performed by using the dose latitude DL(U) and the dimensional variation amount ΔCD(x). The same effect as the first embodiment can also be acquired by this checking.

Next, checking of a dose will be explained.

In the dose D⁺(x) map generation step (S121), the dose D⁺(x) map generation unit 31 calculates a dose D⁺(x) for each mesh region (mesh 1), and generates a D⁺(x) map in which a dose D⁺(x) is defined for each mesh region (mesh 1). The dose D⁺(x) can be obtained by solving the following equation (14). A dose D⁺(x) in which the proximity effect and the loading effect have been corrected is defined in the D⁺(x) map.

D⁺(x)=D_{L}(x)D_{B}(x)Dₚ(x)DM(x) (14)

Here, as described above, D_{B} in which loading effect correction is not considered is used as the base dose D_{B}. The already calculated value can be used for the proximity effect correction dose coefficient Dp(x). The dose modulation amount DM(x) may be read from the storage device 142, or the amount which has already been read can be diverted.

The method of checking a dose is the same as that of the first embodiment. As described above, loading effect correction may be performed by using the dose latitude DL(U) and the dimensional variation amount ΔCD(x). The same effect as the first embodiment can also be acquired by this checking.

In the determination step (S134), the determination unit 24 determines based on whether the following equation (15) is satisfied or not.

$$\frac{{ρ}_{max}^{++} ( x )}{pass} = \frac{{[ {D}_{L} ( x ) {D}_{B} ( x ) ρ ( DM \text{:} x ) {D}_{p} ( x ) ]}_{max} {D}_{f} ( x )}{pass} > {D}_{th}^{( 1 )} \qquad ( 15 )$$

In the determination step (S144), the determination unit 36 determines based on whether the following equation (16) is satisfied or not.

$$\frac{{D}_{max}^{++} ( x )}{pass} = \frac{{[ {D}_{L} ( x ) {D}_{B} ( x ) DM ( x ) {D}_{p} ( x ) ]}_{max} {D}_{f} ( x )}{pass} > {D}_{th}^{( 2 )} \qquad ( 16 )$$

The embodiments have been explained referring to concrete examples described above. However, the present invention is not limited to these specific examples.

While the apparatus configuration, control method, and the like not directly necessary for explaining the present invention are not described, some or all of them may be suitably selected and used when needed. For example, although description of the configuration of a control unit for controlling the writing apparatus 100 is omitted, it should be understood that some or all of the configuration of the control unit is to be selected and used appropriately when necessary.

In addition, any other charged particle beam writing apparatus and a method thereof, and a method of checking a dose of a charged particle beam that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A charged particle beam writing apparatus comprising:
a calculation unit configured to calculate a dose density that corrects a dimensional variation caused by at least one of a proximity effect, a fogging effect, and a loading effect, and indicates a dose per unit area of a charged particle beam, where the dose density has been modulated based on a dose modulation amount input from outside;
a determination unit configured to determine whether the dose density exceeds an acceptable value; and
a writing unit configured to write a pattern on a target object with the charged particle beam.

2. The apparatus according to claim 1,
wherein the dose density corrects the dimensional variation caused by the proximity effect and the loading effect, and is defined by using a base dose, a dose coefficient for correcting the dimensional variation caused by the proximity effect and the loading effect, and a pattern area density which is weighted by the dose modulation amount.

3. The apparatus according to claim 1, further comprising:
a dose density map generation unit configured to generate a dose density map in which the dose density is defined for each first mesh region obtained by virtually dividing, by a first size, a chip region of a chip to be written in a writing region of the target object into a plurality of first mesh regions; and
a maximum dose density map generation unit configured to generate a maximum dose density map in which a maximum dose density is defined for each second mesh region obtained by virtually dividing, by a second size larger than the first size, the writing region of the target object into a plurality of second mesh regions, wherein the maximum dose density is selected from dose densities defined for first mesh regions of the plurality of first mesh regions which overlap with at least a part of the each second mesh region.

4. The apparatus according to claim 1, further comprising:
a storage device configured to store an area density; and
a dimensional variation amount calculation unit configured to read the area density from the storage device and calculate a dimensional variation amount caused by the loading effect.

5. The apparatus according to claim 4, further comprising:
a storage device configured to store first correlation data between a proximity effect correction coefficient and the dimensional variation amount, and second correlation data between a base dose and the dimensional variation amount; and
an acquisition unit configured to read the first correlation data and the second correlation data from the storage device, and acquire a group of a base dose and a proximity effect correction coefficient suitable for correcting the dimensional variation amount caused by the loading effect while maintaining proximity effect correction.

6. The apparatus according to claim 5, further comprising:
a storage device configured to store an area density which has been weighted by the dose modulation amount; and
a proximity effect correction dose coefficient calculation unit configured to read the area density which has been weighted from the storage device, and calculate a proximity effect correction dose coefficient for correcting the proximity effect by using the proximity effect correction coefficient having been acquired.

7. A charged particle beam writing apparatus comprising:
a calculation unit configured to calculate a dose of a charged particle beam for correcting a dimensional variation caused by at least one of a proximity effect, a fogging effect, and a loading effect, where the dose has been modulated based on a dose modulation amount input from outside;
a determination unit configured to determine whether the dose exceeds an acceptable value; and
a writing unit configured to write a pattern on a target object with the charged particle beam.

8. The apparatus according to claim 7, further comprising:
a storage device configured to store an area density; and
a dimensional variation amount calculation unit configured to read the area density from the storage device and calculate a dimensional variation amount caused by the loading effect.

9. The apparatus according to claim 8, further comprising:
a storage device configured to store first correlation data between a proximity effect correction coefficient and the dimensional variation amount, and second correlation data between a base dose and the dimensional variation amount; and
an acquisition unit configured to read the first correlation data and the second correlation data from the storage device, and acquire a group of a base dose and a proximity effect correction coefficient suitable for correcting the dimensional variation amount caused by the loading effect while maintaining proximity effect correction.

10. The apparatus according to claim 9, further comprising:
a storage device configured to store an area density which has been weighted by the dose modulation amount; and
a proximity effect correction dose coefficient calculation unit configured to read the area density which has been weighted from the storage device, and calculate a proximity effect correction dose coefficient for correcting the proximity effect by using the proximity effect correction coefficient having been acquired.

11. A charged particle beam dose check method comprising:
calculating a dose or a dose density, which indicates a dose per unit area, of a charged particle beam for correcting a dimensional variation caused by at least one of a proximity effect, a fogging effect, and a loading effect, where the dose or the dose density has been modulated based on a dose modulation amount input from outside; and
determining, before performing writing processing, whether the dose or the dose density exceeds a corresponding acceptable value, and outputting a result of the determining.
